(19) United States
(12) Patent Application Publication
(10) Pub. No.: US 2026/0025951 A1
(43) Pub. Date: Jan. 22, 2026

(54) 3D MICROCRYSTALLINE HEAT DISSIPATION DEVICE

(71) Applicant: Chintung LIN, New Taipei (CN)

(72) Inventor: Chintung LIN, New Taipei (CN)

(21) Appl. No.: 18/953,134

(22) Filed: Nov. 20, 2024

(30) Foreign Application Priority Data
Jul. 17, 2024 (CN) 2024216958289

(51) Int. Cl. H05K 7/20

(52) U.S. Cl. CPC H05K 7/20336

(57) ABSTRACT

A 3D microcrystalline heat dissipation device comprising a capillary phase change heat conduction cavity and a liquid flow heat dissipation cavity that are attached to each other. The capillary phase change heat conduction cavity is configured to be a sealing structure, and the liquid flow heat dissipation cavity is hermetically connected to a liquid inlet pipe and a liquid outlet pipe. The liquid flow heat dissipation cavity has an immersed microcrystalline structure. The bottom surface of the interior of the liquid flow heat dissipation cavity is provided with a microcrystalline copper powder electroplating layer. The heat of the heat source is conducted to the liquid flow heat dissipation cavity through the gas-liquid phase change of the capillary phase change heat conduction cavity, and then the liquid flow heat dissipation cavity quickly brings heat to the outside through the flowing refrigerant, so that efficient heat dissipation is achieved.

### TECHNICAL FIELD

This invention generally relates to the technical field of heat dissipation of electronic products, and more particularly, to a 3D microcrystalline heat dissipation device.

### BACKGROUND

Along with the fast development of computer technologies, especially the artificial intelligence and automatic control, the operating performances of relevant modules or components have also been significantly improved. Taking an AI (artificial intelligence) chip as an example, to match the improved performances, the computation burden of the chip becomes increasingly heavy, and correspondingly, the heat generated by the chip is drastically increased. Therefore, the heat dissipation of heat sources with high heat has become a problem that needs to be solved urgently.

In the prior art, the main technical means for dissipating heat of heat sources is to increase the heat dissipation area by using heat dissipation fins. To improve the heat dissipation efficiency, air cooling is adopted to enhance the heat exchange efficiency. Recently, liquid cooling is also adopted for heat dissipation of heat sources with high heat. Liquid cooling utilizes the heat conduction of liquids to realize heat absorbing and transfer, thereby lowering the temperature of equipment. However, a liquid cooling heat dissipation device mainly conducts heat of the heat source through a metal plate, and the heat of the heat source needs to be conducted to the refrigerant via the metal plate, thereby taking away the heat through the flow of the refrigerant. Due to the poor heat conduction performance of the metal plate, the overall heat dissipation efficiency is low, resulting in the failure of meeting the technical requirement on heat dissipation efficiency.

Along with the technical progress, the concept of a three-dimensional heat dissipation device for heat sources with high heat has been proposed. In the prior art, the three-dimensional heat dissipation device is normally in contact with the heat source via a heat conduction seat, and a plurality of heat dissipation columns or heat dissipation pipes are distributed on the heat conduction seat. The heat of the heat source is transferred by means of the contact between the heat conduction seat and the heat source, and the heat is dissipated through the heat dissipation columns or the heat dissipation pipes.

To solve the prior problems, it is urgent to develop a 3D (three-dimensional) microcrystalline heat dissipation device used for heat sources with high heat such as AI chips.

### SUMMARY

The purpose of the present invention is to provide a 3D (three dimensional) microcrystalline heat dissipation device. According to the present invention, the heat of the heat source is conducted to the liquid flow heat dissipation cavity through the gas-liquid phase change of the capillary phase change heat conduction cavity, and then the liquid flow heat dissipation cavity quickly brings heat to the outside through the flowing refrigerant, so that ideal heat dissipation effect is achieved.

To achieve the above purpose, the present invention adopts the following technical solution: a 3D microcrystalline heat dissipation device comprises a capillary phase change heat conduction cavity and a liquid flow heat dissipation cavity that are attached to each other. The capillary phase change heat conduction cavity is configured to be a sealing structure, and the liquid flow heat dissipation cavity is hermetically connected to a liquid inlet pipe and a liquid outlet pipe.

In another preferred embodiment of the present invention, the liquid flow heat dissipation cavity is a heat dissipation cavity having an immersed microcrystalline structure. The bottom surface of the interior of the liquid flow heat dissipation cavity having the immersed microcrystalline structure is provided with the microcrystalline copper powder electroplating layer.

In another preferred embodiment of the present invention, the lower wall surface of the liquid flow heat dissipation cavity is partially or completely provided with the microcrystalline copper powder electroplating layer, and the upper wall surface of the liquid flow heat dissipation cavity is not provided with the microcrystalline copper powder electroplating layer. Alternatively, the lower wall surface of the liquid flow heat dissipation cavity is partially or completely provided with the microcrystalline copper powder electroplating layer, and the upper wall surface of the liquid flow heat dissipation cavity is partially or completely provided with the microcrystalline copper powder electroplating layer.

The 3D microcrystalline heat dissipation device further comprises a lower cover, a middle partition plate and an upper cover. The middle partition plate seals and covers the lower cover to form the capillary phase change heat conduction cavity, and the upper cover is sealed and buckled with the middle partition plate to form the liquid flow heat dissipation cavity.

In another preferred embodiment of the present invention, the middle partition plate is provided with a plate body and a plurality of flow blocking members for delaying the flow rate of the refrigerant while increasing the heat dissipation area. All the flow blocking members are welded or integrally connected to an upper surface of the plate body, and the flow blocking members are located inside the liquid flow heat dissipation cavity.

In another preferred embodiment of the present invention, the plate body is partially or completely provided with the microcrystalline copper powder electroplating layer, and the outer surface of all or part of the flow blocking members is provided with the microcrystalline copper powder electroplating layer.

In another preferred embodiment of the present invention, the middle partition plate is further provided with a first shovel-tooth heat sink, the first shovel-tooth heat heat sink is fixedly connected to the upper surface of the plate body of the middle partition plate, and the first shovel-tooth heat sink is located inside the liquid flow heat dissipation cavity.

In another preferred embodiment of the present invention, the upper cover is provided with the cover body and the flow blocking piece for delaying the flow rate of the refrigerant. The flow blocking piece is welded or integrally connected to the upper surface of the plate body, and the flow blocking piece is located inside the liquid flow heat dissipation cavity.

In another preferred embodiment of the present invention, the cover body is partially or completely provided with the microcrystalline copper powder electroplating layer, and the outer surface of all or part of the flow blocking pieces is provided or not provided with the microcrystalline copper powder electroplating layer.

In another preferred embodiment of the present invention, the upper cover is further provided with a second shovel-tooth heat sink, and the second shovel-tooth heat sink is fixedly connected to the upper surface of the cover body of the upper cover.

The 3D microcrystalline heat dissipation device further comprises a heat pipe for heat dissipation. The heat pipe is fixedly connected to the interior of the liquid flow heat dissipation cavity, and two ends of the heat pipe are closed. The inner wall surface of the heat pipe is provided with the microcrystalline copper powder electroplating layer, and the interior of the heat pipe is in a vacuum state and is filled with the refrigerant.

In another preferred embodiment of the present invention, the outer surface of the heat pipe is provided with the microcrystalline copper powder electroplating layer, or the outer surface of the heat pipe is not provided with the microcrystalline copper powder electroplating layer.

In another preferred embodiment of the present invention, the inner wall surface of the capillary phase change heat conduction cavity is provided with the microcrystalline copper powder electroplating layer, and the interior of the capillary phase change heat conduction cavity is in a vacuum state and is filled with the refrigerant.

The 3D microcrystalline heat dissipation device of the present invention comprises a capillary phase change heat conduction cavity and a liquid flow heat dissipation cavity that are attached to each other. The capillary phase change heat conduction cavity is configured to be a sealing structure, and the liquid flow heat dissipation cavity is hermetically connected to a liquid inlet pipe and a liquid outlet pipe. The heat of the heat source is conducted to the liquid flow heat dissipation cavity through the gas-liquid phase change of the capillary phase change heat conduction cavity, and then the liquid flow heat dissipation cavity quickly brings heat to the outside through the flowing refrigerant, so that efficient heat dissipation is achieved.

### BRIEF DESCRIPTION OF THE DRAWINGS

The present invention is further described with reference to the accompanying drawings, but the content in the drawings does not constitute any limitation to the present invention.

FIG. 1 is a schematic diagram illustrating a three-dimensional structure of the 3D microcrystalline heat dissipation device;

FIG. 2 is a schematic diagram illustrating a sectional view of the 3D microcrystalline heat dissipation device in embodiment 1;

FIG. 3 is a schematic diagram illustrating a sectional view of the 3D microcrystalline heat dissipation device in embodiment 2;

FIG. 4 is a schematic diagram illustrating a sectional view of the 3D microcrystalline heat dissipation device in embodiment 3;

FIG. 5 is a schematic diagram illustrating a sectional view of the 3D microcrystalline heat dissipation device in embodiment 4;

FIG. 6 is a schematic diagram illustrating a three-dimensional structure of the middle partition plate with the cuboid flow blocking member;

FIG. 7 is a schematic diagram illustrating a three-dimensional structure of the middle partition plate with the prismatic flow blocking member;

FIG. 8 is a schematic diagram illustrating a three-dimensional structure of the middle partition plate with the cylindrical flow blocking member;

FIG. 9 is a schematic diagram illustrating a three-dimensional structure of the middle partition plate with the irregular-shaped flow blocking member;

FIG. 10 is a schematic diagram illustrating a sectional view of the 3D microcrystalline heat dissipation device in embodiment 5;

FIG. 11 is a schematic diagram illustrating a three-dimensional structure of the upper cover;

FIG. 12 is a schematic diagram illustrating a sectional view of the 3D microcrystalline heat dissipation device in embodiment 6;

FIG. 13 is a schematic diagram illustrating a sectional view of the 3D microcrystalline heat dissipation device in embodiment 7;

FIG. 14 is a schematic diagram illustrating a sectional view of the 3D microcrystalline heat dissipation device in embodiment 8;

FIG. 15 is a schematic diagram illustrating a sectional view of the 3D microcrystalline heat dissipation device in embodiment 9;

FIG. 16 is a schematic diagram illustrating a sectional view of the 3D microcrystalline heat dissipation device in embodiment 10;

FIG. 17 is a schematic diagram illustrating a sectional view of the 3D microcrystalline heat dissipation device in embodiment 11;

FIG. 18 is a schematic diagram illustrating a sectional view of the 3D microcrystalline heat dissipation device in embodiment 11;

FIG. 19 is a schematic diagram illustrating a sectional view of the 3D microcrystalline heat dissipation device in embodiment 12;

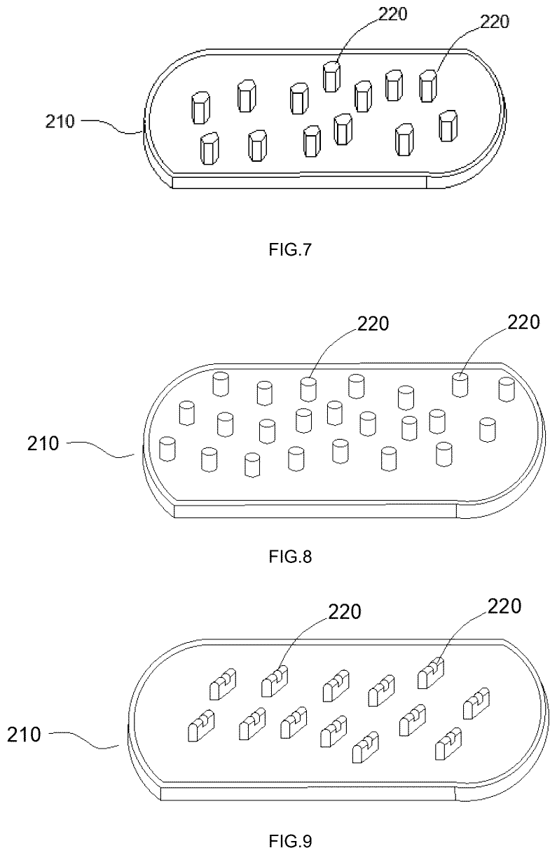

In FIGS. 1-19: 10—Capillary Phase Change Heat Conduction Cavity, 20—Liquid Flow Heat Dissipation Cavity, 100—Upper Cover, 110—Cover Body, 120—Liquid Inlet Pipe, 130—Liquid Outlet Pipe, 140—Flow Blocking Piece, 150—The Second Shovel-tooth Heat Sink, 200—Middle Partition Plate, 210—Plate Body, 220—Flow Blocking Member, 230—The First Shovel-tooth Heat Sink, 300—Lower Cover, 400—Heat Pipe, 500—Microcrystalline Copper Powder Electroplating Layer.

### DETAILED DESCRIPTION

Detailed embodiments are combined hereinafter to further elaborate the technical solution of the present invention.

### Embodiment 1

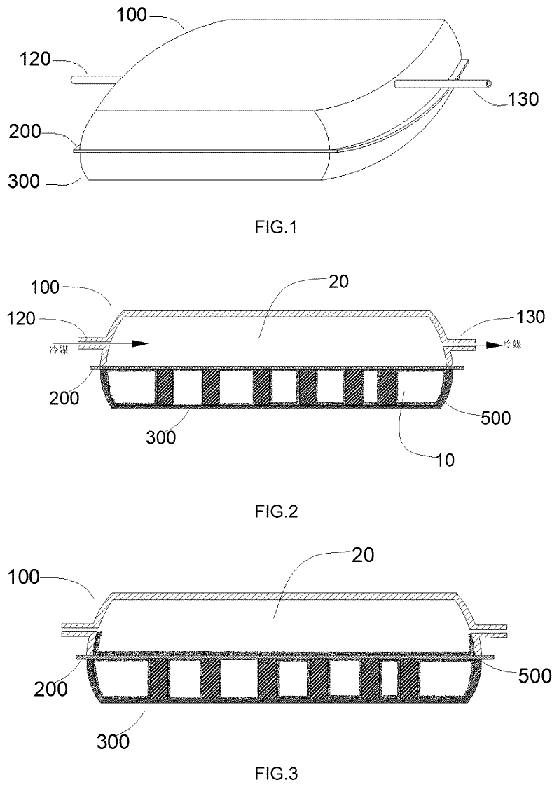

Referring to FIGS. 1-2, a 3D (three dimensional) microcrystalline heat dissipation device comprises a capillary phase change heat conduction cavity 10 and a liquid flow heat dissipation cavity 20 that are attached to each other. The capillary phase change heat conduction cavity 10 is configured to be a sealing structure, and the liquid flow heat dissipation cavity 20 is hermetically connected to a liquid inlet pipe 120 and a liquid outlet pipe 130.

The 3D microcrystalline heat dissipation device further comprises a lower cover 300, a middle partition plate 200 and an upper cover 100. The middle partition plate 200 seals and covers the lower cover 300 to form the capillary phase change heat conduction cavity 10, and the upper cover 100 is sealed and buckled with the middle partition plate 200 to form the liquid flow heat dissipation cavity 20.

In the present invention, the liquid flow heat dissipation cavity 20 is capable of quickly taking away the heat of the middle partition plate 200 through a flowing refrigerant. In the liquid flow heat dissipation cavity 20, the refrigerant may be water, alcohol, acetone, R12, Freon or other substances. Specifically, in this embodiment, the refrigerant in the liquid flow heat dissipation cavity 20 is Freon, and the refrigerant in the capillary phase change heat conduction cavity 10 is water. The refrigerant in the liquid flow heat dissipation cavity 20 may be the same as or different from the refrigerant in the capillary phase change heat conduction cavity 10, which may be selected depending on the actual situation.

It is worth mentioning that when the 3D microcrystalline heat dissipation device of the present invention is used, a lower surface of the lower cover 300 is attached to a heat source.

An inner wall surface of the capillary phase change heat conduction cavity 10 is provided with a microcrystalline copper powder electroplating layer 500, and the interior of the capillary phase change heat conduction cavity 10 is in a vacuum state and is filled with a refrigerant.

It is worth mentioning that, the microcrystalline copper powder electroplating layer 500 is prepared by using a copper powder metal plating layer, a metal substrate, an energy-saving and anti-swelling 3D microcrystalline heat dissipation device and a preparation process thereof disclosed in Chinese patent CN107557825B. Moreover, a column body or a support rib is further provided inside the capillary phase change heat conduction cavity 10, and the column body and the support rib are welded or integrally connected to an inner surface of the capillary phase change heat conduction cavity 10. The heat dissipation principle of the capillary phase change heat conduction cavity 10 of the present invention is the same as that of the Chinese patent CN107557825 B. Namely, when the capillary phase change heat conduction cavity 10 is in a non-heated state, the refrigerant in the capillary phase change heat conduction cavity 10 is accommodated in the copper powder metal plating layer and is basically in a saturated state. When the capillary phase change heat conduction cavity 10 is heated by the heat source, the refrigerant in the copper powder metal plating layer of the lower cover 300 is heated and then evaporated. At this point, some of the vapor reaches the middle partition plate 200 and is cooled, and some of the vapor encounters the column body or the copper powder metal plating layer on a surface of the support rib and is then cooled. After condensation, the refrigerant flows back to the lower cover 300 along the column body or the support rib. In this way, the circulation of dissipating heat from a lower wall surface to an upper wall surface is continuously realized. The capillary phase change heat conduction cavity 10 is not a focus of the present invention. Specifically, the capillary phase change heat conduction cavity 10 is the same as an inner cavity of the copper powder metal plating layer having a refrigerant gas-liquid phase change function and an inner cavity of the 3D microcrystalline heat dissipation device in the prior art. The focus of the present invention is that the 3D microcrystalline heat dissipation device is provided with the liquid flow heat dissipation cavity 20.

The refrigerant enters the liquid flow heat dissipation cavity 20 from the liquid inlet pipe 120 and is then discharged from the liquid outlet pipe 130, thereby quickly taking away the heat that the capillary phase change heat conduction cavity 10 absorbs from the heat source. Compared with the 3D microcrystalline heat dissipation device provided with the microcrystalline copper powder electroplating layer 500 in the prior art, the heat dissipation effect of the present invention is further improved.

The 3D microcrystalline heat dissipation device performs gas-liquid phase change through the refrigerant in the capillary phase change heat conduction cavity 10, thereby allowing the heat of the heat source to be conducted to the liquid flow heat dissipation cavity 20 and is then taken away to the outside through the flowing refrigerant in the liquid flow heat dissipation cavity 20. Thus, efficient heat dissipation is achieved.

### Embodiment 2

Referring to FIG. 3, in this embodiment, the features of the 3D microcrystalline heat dissipation device are the same as those in Embodiment 1 except for the following: the liquid flow heat dissipation cavity 20 is a heat dissipation cavity having an immersed microcrystalline structure, and the bottom surface of the interior of the liquid flow heat dissipation cavity having the immersed microcrystalline structure is provided with the microcrystalline copper powder electroplating layer 500.

More specifically, in this embodiment, the microcrystalline copper powder electroplating layer 500 is partially or completely arranged on the lower wall surface of the liquid flow heat dissipation cavity 20, and the upper wall surface of the liquid flow heat dissipation cavity 20 is not provided with the microcrystalline copper powder electroplating layer 500. Specifically, in this embodiment, the microcrystalline copper powder electroplating layer 500 is arranged on the lower wall surface of the liquid flow heat dissipation cavity 20.

It is worth mentioning that, in this embodiment, a plurality of gaps are formed in the microcrystalline copper powder electroplating layer 500 for accommodating the refrigerant. When the middle partition plate 200 absorbs heat, the capillary phenomenon of the microcrystalline copper powder electroplating layer 500 enables the refrigerant to be discharged outwards, thereby making the refrigerant move. In this way, the refrigerant flows to the outside and is discharged from a liquid outlet. At this point, new refrigerant is supplemented into the gaps of the microcrystalline copper powder electroplating layer 500, so that the heat of the middle partition plate 200 is quickly taken away.

Experiments prove that, under same conditions, compared with the 3D microcrystalline heat dissipation device in Embodiment 1, the heat dissipation efficiency of the 3D microcrystalline heat dissipation device in this embodiment is improved by 35%.

### Embodiment 3

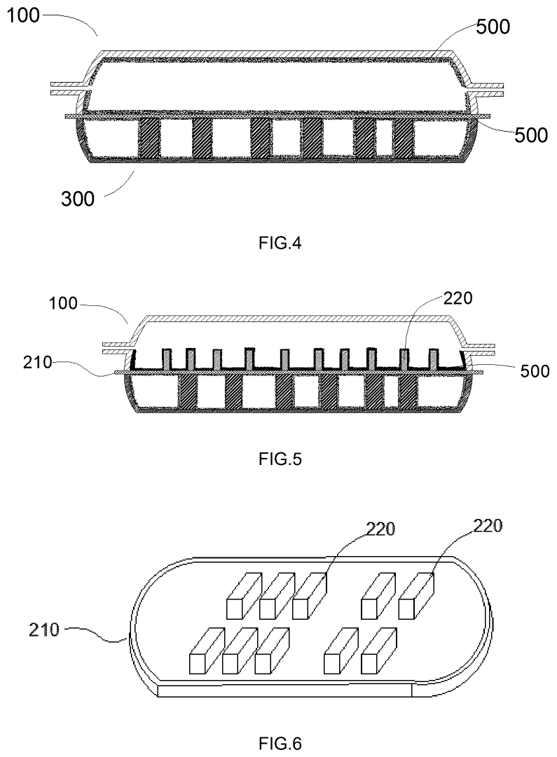

Referring to FIG. 4, in this embodiment, the features of the 3D microcrystalline heat dissipation device are the same as those in Embodiment 2 except for the following: the lower wall surface of the liquid flow heat dissipation cavity 20 is completely provided with the microcrystalline copper powder electroplating layer 500, and the upper wall surface of the liquid flow heat dissipation cavity 20 is completely provided with the microcrystalline copper powder electroplating layer 500.

Compared with embodiment 2, in embodiment 3, the microcrystalline copper powder electroplating layer 500 is provided on both the upper wall surface and the lower wall surface of the liquid flow heat dissipation cavity 20, so that the area of the microcrystalline copper powder electroplating layer 500 is increased, and the heat dissipation effect is further enhanced.

### Embodiment 4

Referring to FIG. 5, in this embodiment, the features of the 3D microcrystalline heat dissipation device are the same as those in Embodiment 1 except for the following: the middle partition plate 200 is provided with a plate body 210 and a plurality of flow blocking members 220 for delaying the flow rate of the refrigerant while increasing the heat dissipation area. All the flow blocking members 220 are welded or integrally connected to an upper surface of the plate body 210, and the flow blocking members 220 are located inside the liquid flow heat dissipation cavity 20. More specifically, the flow blocking members 220 are integrally connected to the upper surface of the plate body 210. The lower wall surface of the liquid flow heat dissipation cavity 20 is provided with the microcrystalline copper powder electroplating layer 500, and the upper wall surface of the liquid flow heat dissipation cavity 20 is not provided with the microcrystalline copper powder electroplating layer 500. The plate body 210 is completely provided with the microcrystalline copper powder electroplating layer 500, and the outer surface of all the flow blocking members 220 is provided with the microcrystalline copper powder electroplating layer 500.

It is worth mentioning that, in this embodiment, a part of the flow blocking members 220 may be provided with the microcrystalline copper powder electroplating layer 500, and the other part of the flow blocking members may not be provided with the microcrystalline copper powder electroplating layer 500.

In embodiment 4, the effect of the microcrystalline copper powder electroplating layer 500 of the liquid flow heat dissipation cavity 20 is the same as that in Embodiment 2. The flow blocking member 220 in embodiment 4 plays a role in blocking the refrigerant and prolonging the flowing duration of the refrigerant in the liquid flow heat dissipation cavity 20. The flow blocking member 220 also increases the surface area of the middle partition plate 200, thereby improving the heat conduction effect with the refrigerant.

Specifically, in this embodiment, the shape of the flow blocking member 220 is configured to be cylindrical. However, the shape of the flow blocking member 220 is not limited to be cylindrical, which may also be prismatic, cuboid or other irregular shapes. Referring to FIGS. 6-9, the flow blocking member 220 may be configured to be any shapes as long as the flow blocking member 220 is capable of blocking the flow of the refrigerant.

Compared with Embodiment 2, in this embodiment, by adding the flow blocking members 220, the flowing duration of the refrigerant in the liquid flow heat dissipation cavity 20 is prolonged, and the duration of contact between the refrigerant and the liquid flow heat dissipation cavity 20 is increased. Meanwhile, by means of arranging the flow blocking members, the surface area of the middle partition plate 200 is increased and the contact area with the refrigerant is increased, so that the heat dissipation effect is further improved.

### Embodiment 5

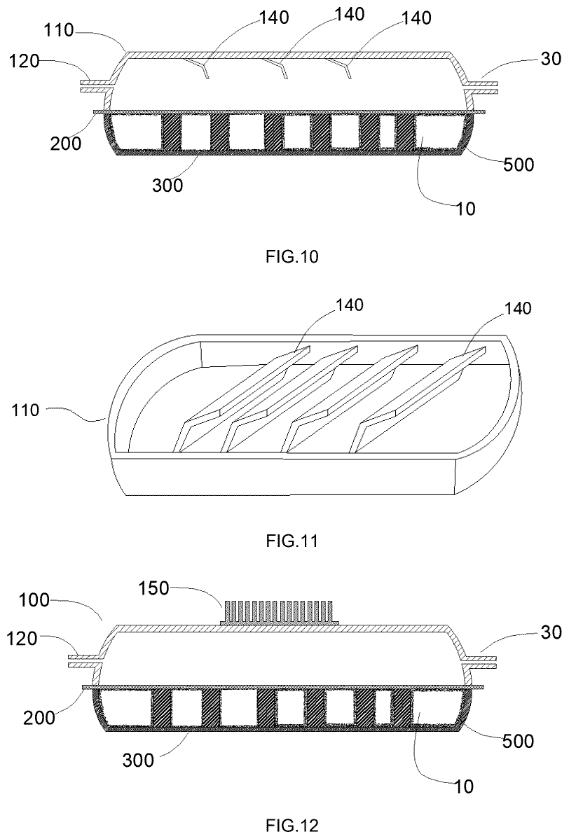

Referring to FIGS. 10-11, in this embodiment, the features of the 3D microcrystalline heat dissipation device are the same as those in Embodiment 1 except for the following: the upper cover 100 is provided with a cover body 110 and a flow blocking piece 140 for delaying the flow rate of the refrigerant. The flow blocking piece 140 is fixedly connected to an upper surface of an inner side of the cover body 110, and the flow blocking piece 140 is located inside the liquid flow heat dissipation cavity 20. The flow blocking piece 140 plays a role in blocking the refrigerant, thereby prolonging the flowing duration of the refrigerant in the liquid flow heat dissipation cavity 20.

Compared with Embodiment 1, in this embodiment, by adding the flow blocking piece 140, the flowing duration of the refrigerant in the liquid flow heat dissipation cavity 20 is prolonged, and the duration of contact between the refrigerant and the liquid flow heat dissipation cavity 20 is increased, so that the heat dissipation effect is further improved.

### Embodiment 6

Referring to FIG. 12, in this embodiment, the features of the 3D microcrystalline heat dissipation device are the same as those in Embodiment 1 except for the following: the upper cover 100 is further provided with a second shovel-tooth heat sink 150, and the second shovel-tooth heat sink 150 is fixedly connected to an upper surface of the cover body 110 of the upper cover 100.

The second shovel-tooth heat sink 150 comprises a plurality of metal sheets arranged in parallel, and the second shovel-tooth heat sink 150 is prepared by using a shovel mechanism. The second shovel-tooth heat sink 150 increases the surface area of the upper cover 100, allowing the heat to be rapidly conducted to the outside.

In this embodiment, by adding the second shovel-tooth heat sink 150 on the upper cover 100, except for taking away heat through the flowing refrigerant, the liquid flow heat dissipation cavity also takes away heat through the air cooling of the second shovel-tooth heat sink 150.

### Embodiment 7

Referring to FIG. 13, in this embodiment, the features of the 3D microcrystalline heat dissipation device are the same as those in Embodiment 1 except for the following: the middle partition plate 200 is provided with the plate body 210, the plurality of flow blocking members 220 and a first shovel-tooth heat sink 230 for delaying the flow rate of the refrigerant while increasing the heat dissipation area. All of the flow blocking members 220 are welded to the upper surface of the plate body 210, and the flow blocking members 220 are located inside the liquid flow heat dissipation cavity 20. The first shovel-tooth heat heat sink 230 is fixedly connected to the lower surface of the plate body 210 of the middle partition plate 200, and the first shovel-tooth heat sink 230 is located inside the liquid flow heat dissipation cavity 20.

The lower wall surface of the liquid flow heat dissipation cavity 20 is partially provided with the microcrystalline copper powder electroplating layer 500, and the upper wall surface of the liquid flow heat dissipation cavity 20 is not provided with the microcrystalline copper powder electroplating layer 500. More specifically, except for the first shovel-tooth heat sink 230, the lower wall surface of the liquid flow heat dissipation cavity 20 is uniformly provided with the microcrystalline copper powder electroplating layer 500, and an outer surface of the flow blocking member 220 is provided with the microcrystalline copper powder electroplating layer 500.

The first shovel-tooth heat sink 230 comprises a plurality of metal sheets arranged in parallel, and the first shovel-tooth heat sink 230 is prepared by using a shovel mechanism. In addition, the first shovel-tooth heat sink 230 plays a role in blocking the refrigerant and prolonging the flowing duration of the refrigerant in the liquid flow heat dissipation cavity 20. The flow blocking member 220 also increases the surface area of the middle partition plate 200. In this embodiment, the outer surface of the first shovel-tooth heat sink 230 is not provided with the microcrystalline copper powder electroplating layer 500.

By simultaneously arranging the flow blocking member 220 and the first shovel-tooth heat sink 230 inside the liquid flow heat dissipation cavity 20, the flowing duration of the refrigerant in the liquid flow heat dissipation cavity 20 is effectively prolonged, thus significantly enhancing the heat exchange with the refrigerant.

### Embodiment 8

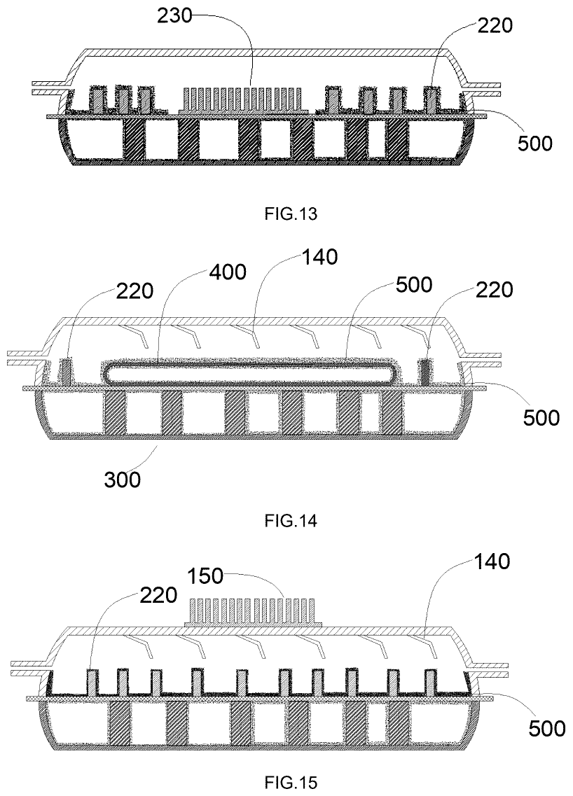

Referring to FIG. 14, in this embodiment, the features of the 3D microcrystalline heat dissipation device are the same as those in Embodiment 1 except for the following: the upper cover 100 is provided with the cover body 110 and the flow blocking piece 140 for delaying the flow rate of the refrigerant. The flow blocking piece 140 is fixedly connected to the upper surface of the inner side of the cover body 110, and the flow blocking piece 140 is located inside the liquid flow heat dissipation cavity 20.

The middle partition plate 200 is provided with the plate body 210 and the plurality of flow blocking members 220 for delaying the flow rate of the refrigerant and increasing the heat dissipation area. All the flow blocking members 220 are fixedly connected to the upper surface of the plate body 210, and the flow blocking members 220 are located inside the liquid flow heat dissipation cavity 20.

In this embodiment, a heat pipe 400 for facilitating heat dissipation is added. The heat pipe 400 is fixedly connected to the interior of the liquid flow heat dissipation cavity 20, and two ends of the heat pipe 400 are closed. The microcrystalline copper powder electroplating layer 500 is arranged on an inner wall surface of the heat pipe 400, and the interior of the heat pipe 400 is in a vacuum state and is filled with the refrigerant. The lower wall surface of the liquid flow heat dissipation cavity 20 is provided with the microcrystalline copper powder electroplating layer 500, and the upper wall surface of the liquid flow heat dissipation cavity 20 is not provided with the microcrystalline copper powder electroplating layer 500.

An outer surface of the heat pipe 400 is provided with the microcrystalline copper powder electroplating layer 500, or the outer surface of the heat pipe 400 is not provided with the microcrystalline copper powder electroplating layer 500. More specifically, in this embodiment, the outer surface of the heat pipe 400 is provided with the microcrystalline copper powder electroplating layer 500. Compared with the heat pipe 400 not provided with the microcrystalline copper powder electroplating layer 500, the heat pipe 400 provided with the microcrystalline copper powder electroplating layer 500 possesses an increased area of the microcrystalline copper powder electroplating layer 500 such that the heat dissipation effect is greatly improved.

It is worth mentioning that, in this embodiment, the microcrystalline copper powder electroplating layer 500 is arranged on the lower wall surface of the liquid flow heat dissipation cavity 20, and the heat pipe 400 plays a role in blocking the refrigerant and prolonging the flowing duration of the refrigerant in the liquid flow heat dissipation cavity 20. Resembling the capillary phase change heat conduction cavity 10, the heat pipe 400 is also capable of transferring the heat of the heat source to the refrigerant of the capillary phase change heat conduction cavity 10 by means of the gas-liquid phase change of the refrigerant.

By simultaneously arranging the flow blocking member 220 and the heat pipe 400 in the liquid flow heat dissipation cavity 20, the flowing duration of the refrigerant in the liquid flow heat dissipation cavity 20 is prolonged, and the effect of heat exchange with the refrigerant is improved. Moreover, the gas-liquid phase change of the refrigerant is performed in the heat pipe 400, which further improves the heat dissipation effect.

### Embodiment 9

Referring to FIG. 15, in this embodiment, the features of the 3D microcrystalline heat dissipation device are the same as those in Embodiment 1 except for the following: the upper cover 100 is provided with the cover body 110, the flow blocking piece 140 and the second shovel-tooth heat sink 150 for delaying the flow rate of the refrigerant. The flow blocking piece 140 is fixedly connected to the upper surface of the inner side of the cover body 110. The flow blocking piece 140 is located inside the liquid flow heat dissipation cavity 20 and is fixedly connected to the upper surface of the cover body 110 of the upper cover 100.

The middle partition plate 200 is provided with the plate body 210 and the plurality of flow blocking members 220 for delaying the flow rate of the refrigerant and increasing the heat dissipation area. All the flow blocking members 220 are fixedly connected to the upper surface of the plate body 210, and the flow blocking members 220 are located inside the liquid flow heat dissipation cavity 20. The lower wall surface of the liquid flow heat dissipation cavity 20 is provided with the microcrystalline copper powder electroplating layer 500, and the upper wall surface of the liquid flow heat dissipation cavity 20 is not provided with the microcrystalline copper powder electroplating layer 500.

Experimental results show that, under same conditions, compared with the 3D microcrystalline heat dissipation device in Embodiment 1, the heat dissipation efficiency of the 3D microcrystalline heat dissipation device in this embodiment is improved by 68%.

### Embodiment 10

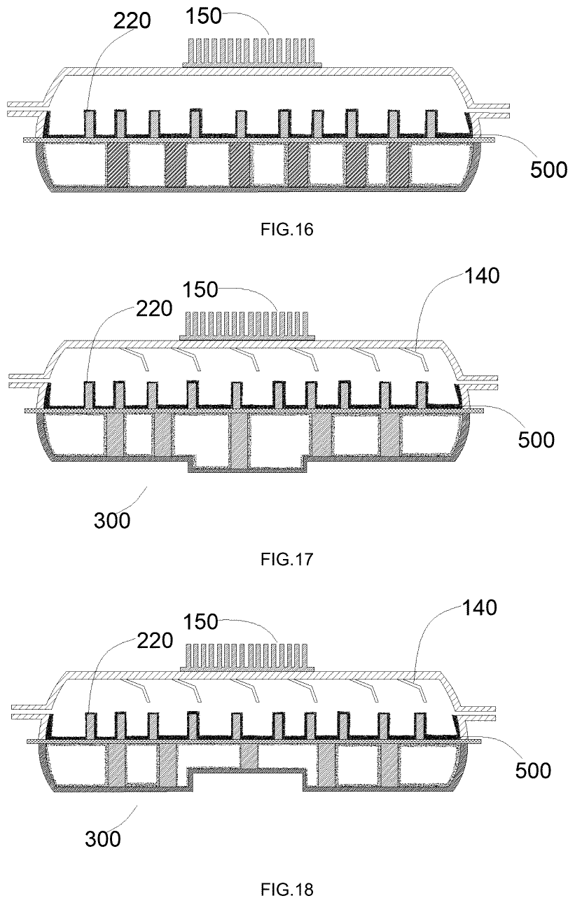

Referring to FIG. 16, in this embodiment, the features of the 3D microcrystalline heat dissipation device are the same as those in Embodiment 1 except for the following: the upper cover 100 is provided with the cover body 110 and the second shovel-tooth heat sink 150, the flow blocking piece 140 is fixedly connected to the lower surface of the cover body 110, and the second shovel-tooth heat sink 150 is fixedly connected to the upper surface of the cover body 110 of the upper cover 100.

The middle partition plate 200 is provided with the plate body 210 and the plurality of flow blocking members 220 for delaying the flow rate of the refrigerant and increasing the heat dissipation area. All the flow blocking members 220 are fixedly connected to the upper surface of the plate body 210, and the flow blocking members 220 are located inside the liquid flow heat dissipation cavity 20. The lower wall surface of the liquid flow heat dissipation cavity 20 is completely provided with the microcrystalline copper powder electroplating layer 500, and the upper wall surface of the liquid flow heat dissipation cavity 20 is not provided with the microcrystalline copper powder electroplating layer 500.

In this embodiment, by adding the second shovel-tooth heat sink 150 on the upper cover 100, except for taking away heat through the flowing refrigerant, the liquid flow heat dissipation cavity also takes away heat through the air cooling of the second shovel-tooth heat sink 150.

### Embodiment 11

Referring to FIG. 17, in this embodiment, the features of the 3D microcrystalline heat dissipation device are the same as those in Embodiment 9 except for the following: in addition to being flat, referring to FIG. 17, the lower surface of the lower cover 300 may protrude downward, and the protrusion may be attached to the heat source. Referring to FIG. 18, the lower surface of the lower cover 300 is recessed upward, and the heat source is embedded in the recessed portion of the lower surface of the lower cover 300. The shape of the lower cover 300 may vary according to the actual situation, thereby allowing the lower cover 300 to be attached with the heat source such that ideal heat dissipation effect is ensured.

### Embodiment 12

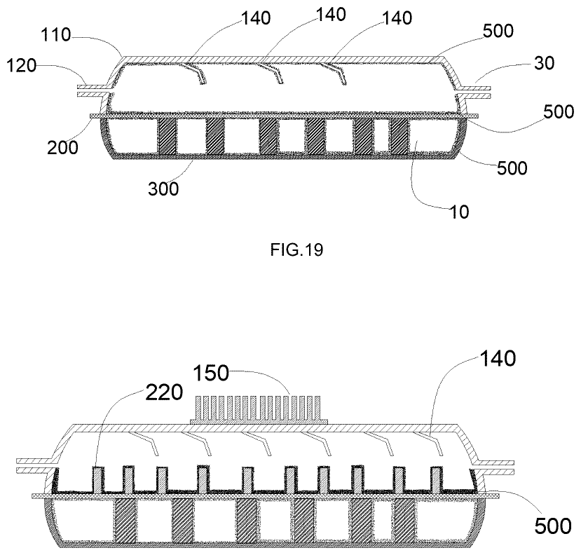

Referring to FIG. 19, in this embodiment, the features of the 3D microcrystalline heat dissipation device are the same as those in Embodiment 9 except for the following: the microcrystalline copper powder electroplating layer 500 is arranged on the outer surface of all or part of the flow blocking pieces 140. In this embodiment, specifically, all of the flow blocking pieces 140 are provided with the microcrystalline copper powder electroplating layer 500. Compared with arranging the microcrystalline copper powder electroplating layer 500 on a part of the flow blocking pieces 140, arranging the microcrystalline copper powder electroplating layer 500 on all of the flow blocking pieces 140 is capable of increasing the coverage rate of the microcrystalline copper powder electroplating layer 500 such that the heat dissipation effect is further improved.

The lower wall surface of the liquid flow heat dissipation cavity 20 is completely provided with the microcrystalline copper powder electroplating layer 500, and the upper wall surface of the liquid flow heat dissipation cavity 20 is completely provided with the microcrystalline copper powder electroplating layer 500.

Compared with embodiment 3, in this embodiment, the arrangement of the flow blocking piece 140 prolongs the flowing duration of the refrigerant, and the flow blocking piece 140 is further provided with the microcrystalline copper powder electroplating layer 500, so that the coverage area of the microcrystalline copper powder electroplating layer 500 is increased, and the heat dissipation effect is improved.

Finally, it should be noted that the above embodiments are merely used to illustrate the technical solutions of the present invention rather than limiting the scope of the present invention. Although the present invention is described in detail with reference to the preferred embodiments, it should be understood by those skilled in the art that modifications or equivalent replacements may be made to the technical solutions of the present invention without departing from the spirit and scope of the technical solutions of the present invention.

What is claimed is:

1. A 3D microcrystalline heat dissipation device, comprising:
a capillary phase change heat conduction cavity, and
a liquid flow heat dissipation cavity that are attached to each other, wherein the capillary phase change heat conduction cavity is configured to be a sealing structure, and wherein the liquid flow heat dissipation cavity is hermetically connected to a liquid inlet pipe and a liquid outlet pipe.

2. The 3D microcrystalline heat dissipation device of claim 1, wherein the liquid flow heat dissipation cavity is a heat dissipation cavity having an immersed microcrystalline structure, and wherein a bottom surface of an interior of the liquid flow heat dissipation cavity having the immersed microcrystalline structure is provided with a microcrystalline copper powder electroplating layer.

3. The 3D microcrystalline heat dissipation device of claim 1, wherein a lower wall surface of the liquid flow heat dissipation cavity is partially or completely provided with the microcrystalline copper powder electroplating layer, wherein an upper wall surface of the liquid flow heat dissipation cavity is not provided with the microcrystalline copper powder electroplating layer, wherein alternatively, a lower wall surface of the liquid flow heat dissipation cavity is partially or completely provided with the microcrystalline copper powder electroplating layer, and wherein an upper wall surface of the liquid flow heat dissipation cavity is partially or completely provided with the microcrystalline copper powder electroplating layer.

4. The 3D microcrystalline heat dissipation device of claims 1-3, wherein the 3D microcrystalline heat dissipation device further comprises:
a lower cover, a middle partition plate and an upper cover, wherein the middle partition plate seals and covers the lower cover to form the capillary phase change heat conduction cavity, and the upper cover is sealed and buckled with the middle partition plate to form the liquid flow heat dissipation cavity.

5. The 3D microcrystalline heat dissipation device of claim 4, wherein the middle partition plate is provided with a plate body and a plurality of flow blocking members for delaying the flow rate of the refrigerant while increasing the heat dissipation area, wherein all the flow blocking members are welded or integrally connected to an upper surface of the plate body, wherein the flow blocking members are located inside the liquid flow heat dissipation cavity, wherein the plate body is partially or completely provided with the microcrystalline copper powder electroplating layer, and wherein an outer surface of all or part of the flow blocking members is provided with the microcrystalline copper powder electroplating layer.

6. The 3D microcrystalline heat dissipation device of claim 4, wherein the middle partition plate is further provided with a first shovel-tooth heat sink, wherein the first shovel-tooth heat heat sink is fixedly connected to an upper surface of the plate body of the middle partition plate, and wherein the first shovel-tooth heat sink is located inside the liquid flow heat dissipation cavity.

7. The 3D microcrystalline heat dissipation device of claim 4, wherein the 3D microcrystalline heat dissipation device further comprises:
a heat pipe for heat dissipation, wherein the heat pipe is fixedly connected to an interior of the liquid flow heat dissipation cavity, wherein two ends of the heat pipe are closed, wherein an inner wall surface of the heat pipe is provided with the microcrystalline copper powder electroplating layer, wherein the interior of the heat pipe is in a vacuum state and is filled with the refrigerant, wherein an outer surface of the heat pipe is provided with the microcrystalline copper powder electroplating layer, or the outer surface of the heat pipe is not provided with the microcrystalline copper powder electroplating layer.

8. The 3D microcrystalline heat dissipation device of claim 4, wherein the upper cover is provided a cover body and a flow blocking piece for delaying the flow rate of the refrigerant, wherein the flow blocking piece is fixedly connected to an upper surface of the plate body, wherein the flow blocking piece is located inside the liquid flow heat dissipation cavity, wherein the cover body is partially or completely provided with the microcrystalline copper powder electroplating layer, and wherein an outer surface of all or part of the flow blocking pieces is provided or not provided with the microcrystalline copper powder electroplating layer.

9. The 3D microcrystalline heat dissipation device of claim 4, wherein the upper cover is further provided with a second shovel-tooth heat sink, and wherein the second shovel-tooth heat sink is fixedly connected to an upper surface of the cover body of the upper cover.

10. The 3D microcrystalline heat dissipation device of claims 1-3, wherein an inner wall surface of the capillary phase change heat conduction cavity is provided with the microcrystalline copper powder electroplating layer, and wherein an interior of the capillary phase change heat conduction cavity is in a vacuum state and is filled with the refrigerant.
